(19) United States
(12) Patent Application Publication
(10) Pub. No.: US 2012/0290895 A1
(43) Pub. Date: Nov. 15, 2012

(54) CONTROLLER FOR DETECTING AND CORRECTING AN ERROR WITHOUT A BUFFER, AND METHOD FOR OPERATING SAME

(75) Inventor: Daeguen Jee, Seongnam-si (KR)

(73) Assignee: INDILINX CO., LTD, Seongnam-si, Gyeonggi-do (KR)

(21) Appl. No.: 13/519,724

(22) PCT Filed: Jan. 8, 2010
(86) PCT No.: PCT/KR2010/000113

§ 371 Date: Jun. 28, 2012

(30) Foreign Application Priority Data
Dec. 28, 2009 (KR) 10-2009-0131512

(51) Int. Cl. G11C 29/04; G06F 11/10

(52) U.S. Cl. 714/758; 714/773; 714/E11.034

(57) ABSTRACT

An operational method of a controller for a flash memory may include receiving target data read out from the flash memory, outputting the received target data to a main memory, and generating an error detection syndrome related to the received target data after or simultaneously with completion of the output of the target data.

### TECHNICAL FIELD

The present invention relates to a controller for a flash memory or for a solid state disk (SSD) including a flash memory, and more particularly to, a technology for detecting and correcting an error in read data.

### BACKGROUND ART

Recently, interest in a flash memory and a solid state disk (SSD) is receiving increased attention. Since the flash memory and the SSD do not need a mechanical driver such as a motor for a hard disk drive (HDD), heat or noise may not be caused during operation of the flash memory and the SSD. Furthermore, the flash memory and the SSD are durable to external impacts and show a relatively high data transmission rate in comparison to the HDD.

Due to manufacturing characteristics of the flash memory, bit errors may occasionally occur when data is read out from the flash memory. Therefore, error correction needs to be performed with respect to the data read out from the flash memory. That is, the flash memory requires error correction with respect to data of a specific bit or more per kilobyte (KB).

In general, a controller includes a buffer. Data read out from the flash memory is temporarily stored in the buffer. The controller performs error correction with respect to the data temporarily stored in the buffer. The buffer included in the controller generally uses a static random access memory (SRAM) and therefore increases the price of the controller. Accordingly, there is a demand for a technology enabling omission of the buffer to reduce the price of the controller.

### DISCLOSURE OF INVENTION

### Technical Goals

According to embodiments of the present invention, a technology which enables manufacturing of a controller at a low cost by detecting and correcting an error present in data read out from a flash memory is provided.

Also, according to embodiments of the present invention, data read out from a flash memory is transmitted directly to a main memory without passing through a buffer. Therefore, data transmission to the main memory may be performed more quickly.

### Technical Solutions

According to an aspect of the present invention, there is provided an operational method of a controller for a flash memory, including receiving target data read out from the flash memory, outputting the received target data to a main memory, and generating an error detection syndrome related to the received target data after or simultaneously with completion of the output of the target data.

The outputting may include outputting the received target data simultaneously with the receiving of the target data, without using a buffer provided in the controller to store the received target data.

The operational method may further include reading out the target data again based on the error detection syndrome.

The operational method may further include calculating, before the target data is read out again, at least one of a location of an error and a corrected value with respect to the error when the error detection syndrome indicates the presence of the error in the received target data.

The operational method may further include outputting new target data to the main memory by inserting the corrected value in the target data read out again.

The generating may include starting generation of the error detection syndrome using Bose, Chaudhuri, and Hocquenghem (BCH) codes during reception of the target data.

The reading may include reading again part of the target data that includes the error.

According to an aspect of the present invention, there is provided a controller for a flash memory, the controller including an interface to receive target data read out from the flash memory and to output the received target data to a main memory, and an error detector to generate an error detection syndrome with respect to the received target data after or simultaneously with completion of the output of the target data.

The interface may output the received target data directly to the main memory without using a buffer provided in the controller to store the received target data.

The controller may further include a command generator to generate a command for reading out the target data again based on the error detection syndrome.

The error detector may calculate, before the target data is read out again, at least one of a location of an error and a corrected value with respect to the error when the error detection syndrome indicates presence of the error in the received target data.

The error detector may generate a command for inserting the corrected value in the target data read out again so as to generate new target data, and the interface may output the new target data to the main memory.

The error detector may start generation of the error detection syndrome using BCH codes during reception of the target data.

### Effects

Embodiments of the present invention may provide a technology for manufacturing of a controller at a low cost by detecting and correcting an error present in data read out from a flash memory, without a buffer.

Also, embodiments of the present invention may transmit data read out from a flash memory directly to a main memory without using a buffer. Therefore, data may be transmitted more quickly to the main memory.

### BRIEF DESCRIPTION OF DRAWINGS

FIG. 1 is a block diagram illustrating a flash memory and a controller according to a related art;

FIG. 2 is a diagram illustrating an example input and output in the controller shown in FIG. 1;

FIG. 3 is a block diagram illustrating a flash memory and a controller according to an embodiment of the present invention;

FIG. 4 is a timing diagram illustrating an example input and output operation in the controller shown in FIG. 3; and

FIG. 5 is an operational flowchart illustrating an operational method of a controller according to an embodiment of the present invention.

### BEST MODE FOR CARRYING OUT THE INVENTION

Reference will now be made in detail to embodiments of the present invention, examples of which are illustrated in the accompanying drawings, wherein like reference numerals refer to the like elements throughout. The embodiments are described below in order to explain the present invention by referring to the figures.

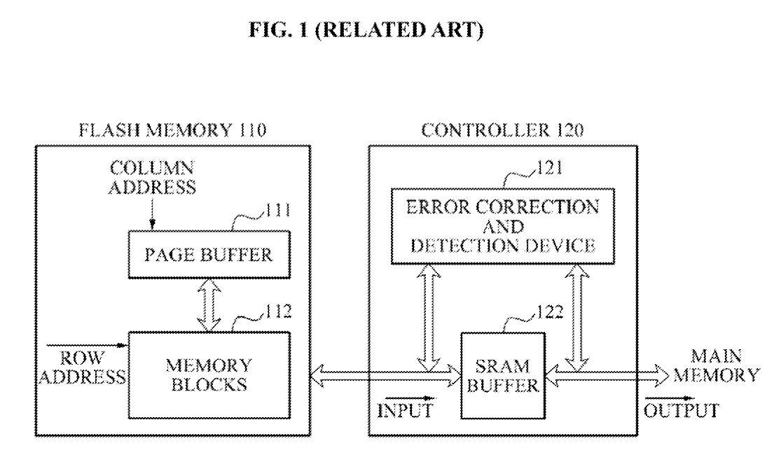

FIG. 1 is a block diagram illustrating a flash memory 110 and a controller 120 according to a related art.

Referring to FIG. 1, the flash memory 110 may include a page buffer 111 and memory blocks 112. The controller 120 may include an error detection and correction device 121 and a static read access memory (SRAM) buffer 122.

The memory blocks 112 of the flash memory 110 may store varied data. A process of reading out data stored in the memory blocks 112 may be briefly described as follows.

1. The controller 120 transmits a read command to the flash memory 110.

2. The flash memory 110 extracts a row address and a column address corresponding to the read command in response to the read command.

3. Data stored in a page corresponding to the row address among the varied data stored in the memory blocks 112 is transmitted to the page buffer 111.

4. Data corresponding to the column address among the data stored in the page buffer 111 is provided to the controller 120.

In this instance, the controller 120 needs to detect an error present in the read data and correct the error. Here, after the SRAM buffer 122 of the controller 120 may temporarily store the read data, the error detection and correction device 121 may perform error detection and correction with respect to the data temporarily stored in the SRAM buffer 122. When the error detection and correction is completed, the data stored in the SRAM buffer 122 may be outputted to the main memory.

In a case in which the data is read out from the flash memory 110, an error usually occurs while the data is transmitted from the memory blocks 112 to the SRAM buffer 122. Therefore, detection and correction of the error present in the data may be performed without the SRAM buffer 122. As aforementioned, the SRAM buffer 122 is the main cause of an increased price of the controller 120. Therefore, omission of the SRAM buffer 122 from the controller 120 may enable manufacturing of the controller 120 at a lower price.

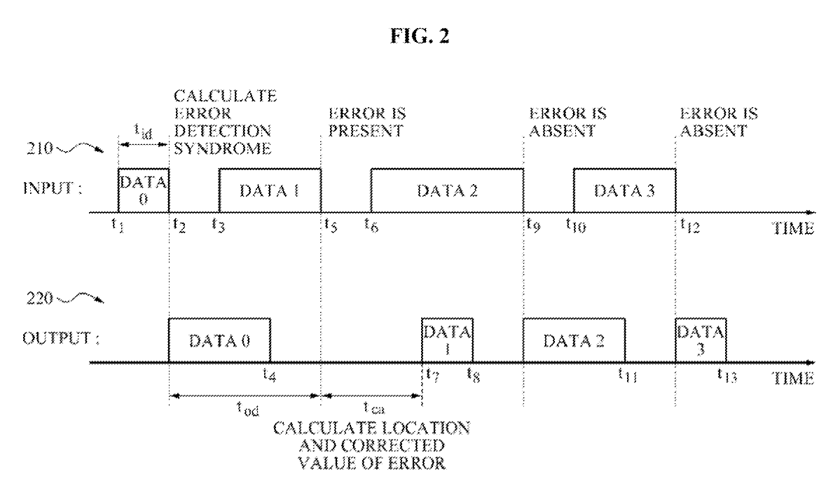

FIG. 2 is a diagram illustrating an example input and output in the controller shown in FIG. 1.

Referring to FIG. 2, data 0, 1, 2, and 3 are sequentially inputted to the controller.

The data 0 inputted during a section from t₁ to t₂ may be stored in the SRAM buffer. The error detection and correction device may calculate the error detection syndrome with respect to the data 0 during the section from t₁ to t₂. Here, the error detection syndrome indicates whether an error is present in the data. A length of the section from t₁ to t₂ refers to a length of an input time section of one piece of data, and to will be referred to as t_{id}. When the data 0 is fully stored in the SRAM buffer, the error detection syndrome is calculated simultaneously. When the data stored in the SRAM buffer does not include any error, the data 0 stored in the SRAM buffer may be outputted to the main memory during a section from t₂ to t₄. Here, length of the section from t₂ to t₄ refers to length of an output time section of one piece of data, and will be referred to as t_{od}.

The data 1 may be inputted during a section from t₃ to t₅ and stored in the SRAM buffer. In the foregoing manner, the error correction and detection device may calculate the error detection syndrome with respect to the data 1 inputted during the section from t₃ to t₅. When the data 1 stored in the SRAM buffer includes an error, the error correction and detection device may calculate a location of the error and a corrected value with respect to the error, during a section from t₅ to t₇. Here, the section from t₅ to t₇ will be referred as tₑₐ. The error correction and detection device may insert the corrected value in the data 1. The corrected data 1 may be outputted from the SRAM buffer to the main memory during a section from t₇ to t₈.

The data 2 may be inputted during a section from t₆ to t₉ and stored in the SRAM buffer. In the foregoing manner, the error correction and detection device may calculate the error detection syndrome with respect to the data 2 inputted during the section from t₆ to t₉. When the data 2 stored in the SRAM buffer does not include an error, the data 2 stored in the SRAM buffer may be outputted to the main memory during a section from t₉ to t₁₁.

The data 3 may be inputted during a section from t₁₀ to t₁₂ and stored in the SRAM buffer. In the foregoing manner, the error correction and detection device may calculate the error detection syndrome with respect to the data 3 inputted during the section from t₁₀ to t₁₂. When the data 3 stored in the SRAM buffer does not include an error, the data 3 stored in the SRAM buffer may be outputted to the main memory during a section from t₁₂ to t₁₃.

Time required for outputting n-number of data through the foregoing process has no connection to the presence of the error in the data and may be expressed by Equation 1.

tₜₒₜₐₗ ≅(t_{id}×n)+t_{od}+α [Equation 1]

Here, n denotes a number of data being outputted or inputted, and α denotes a sum total of time sections among the data being inputted.

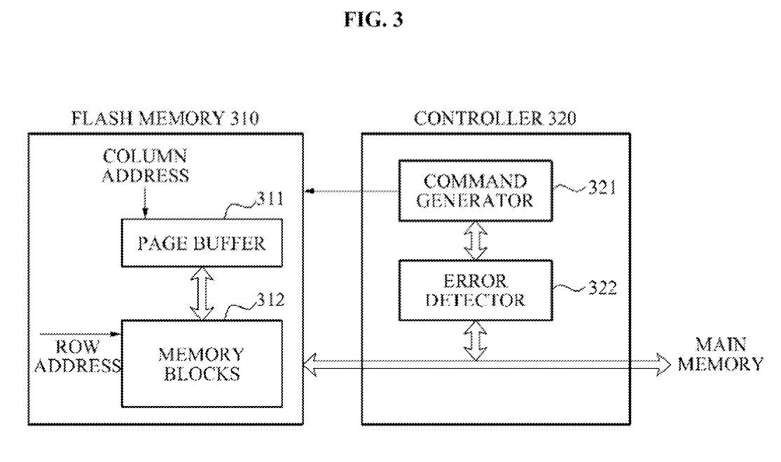

FIG. 3 is a block diagram illustrating a flash memory 310 and a controller 320 according to an embodiment of the present invention

Referring to FIG. 3, the flash memory 310 may include a page buffer 311 and memory blocks 312. The controller 320 may include a command generator 321 and an error detector 322. Different from the embodiment of FIG. 1, the controller 320 may detect and correct an error present in data without using an SRAM buffer, which will be described hereinafter.

The command generator 321 of the controller 320 may transmit, to the flash memory 310, a read command for reading out data. In response to the read command, the flash memory 310 may extract a row address and a column address corresponding to the read command. Data stored in a page corresponding to the row address among various data stored in the memory blocks 312 may be transmitted to the page buffer 311. Data corresponding to the column address among the data stored in the page buffer 311 may be provided to the controller 320.

Data inputted from the flash memory 310 through an interface (not shown in FIG. 3) of the controller 320 may be outputted to the main memory directly through the interface without being stored in the SRAM buffer. The error detector 322 may start generation of an error detection syndrome using Bose, Chaudhuri, and Hocquenghem (BCH) codes during reception of the data. In this regard, the error detector 322 may calculate the error detection syndrome with respect to the data, after or simultaneously with the output of the data.

When the error detection syndrome indicates presence of an error, the error detector 321 may calculate a location of the error and a corrected value with respect to the error before the data is read out again from the flash memory 310. In addition, the command generator 321 may generate a command for reading out the data again and transmit the command to the flash memory 310. In this instance, the command generator 321 may generate a command for reading out an entire part of the data or a command for reading out part of target data that includes the error again.

When the data is read out again from the flash memory 310 according to the command, the error detector 322 may insert the corrected value in the data read out again, thereby generating new data. The new data may be outputted to the main memory through the interface.

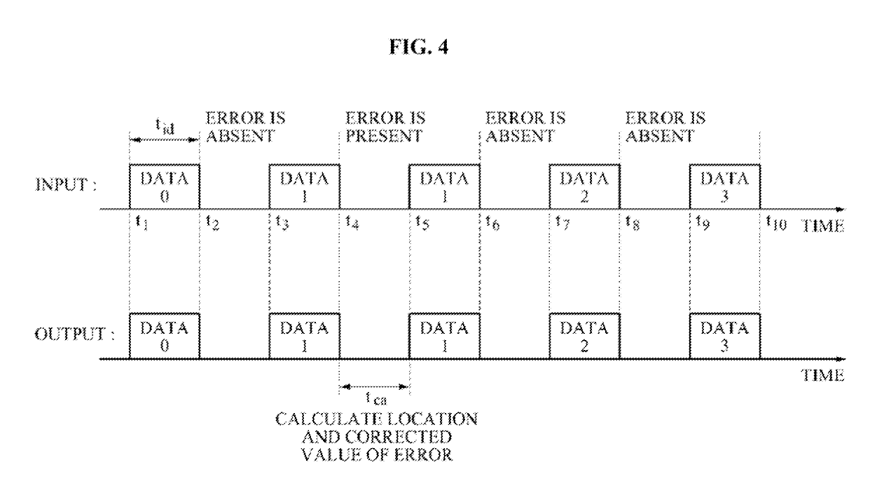

The operation of the respective elements shown in FIG. 3 will be described more specifically with reference to FIG. 4.

FIG. 4 is a timing diagram illustrating an example input and output operation in the controller shown in FIG. 3.

Referring to FIG. 4, the data 0 inputted during the section from t₁ to t₂ may be outputted directly to the main memory without being stored in the SRAM buffer. While the data 0 is being inputted, the error detector may perform error detection with respect to the data 0.

When the data 0 does not include the error, the data 1 may be inputted during the section t₃ to t₄. In the foregoing manner, the error detector may calculate the error detection syndrome with respect to the data 1 inputted during the section from t₃ to t₄. Here, when the data 1 includes the error, the error detector may calculate the location of the error and the corrected value with respect to the error, during a section from t₄ to t₅. In addition, the command generator may generate a command for reading out the data 1 again from the flash memory.

In response to the command, the data 1 may be inputted again to the controller during a section from t₅ to t₆. Here, the error detector may output new data 1 being inputted again, in which the corrected value with respect to the error is inserted at a corresponding location, to the main memory during the section from t₅ to t₆.

The data 2 is inputted to the controller during the section from t₇ to 18. The data 2 may be outputted directly to the main memory. When the data 2 does not include the error, the data 3 may be inputted to the controller during the section from t₉ to t₁₀ and outputted directly to the main memory.

Time required for outputting n-number of data through the foregoing process may be expressed by Equation 2.

tₜₒₜₐₗ≅(t_{id}×n)+(t_{id}×m)+α [Equation 2]

Here, t_{id} denotes a length of an input time section of one piece of data, m denotes a number of data including at least one error, that is, the data requested to be read out again, and α denotes a sum total of time sections among the data being inputted.

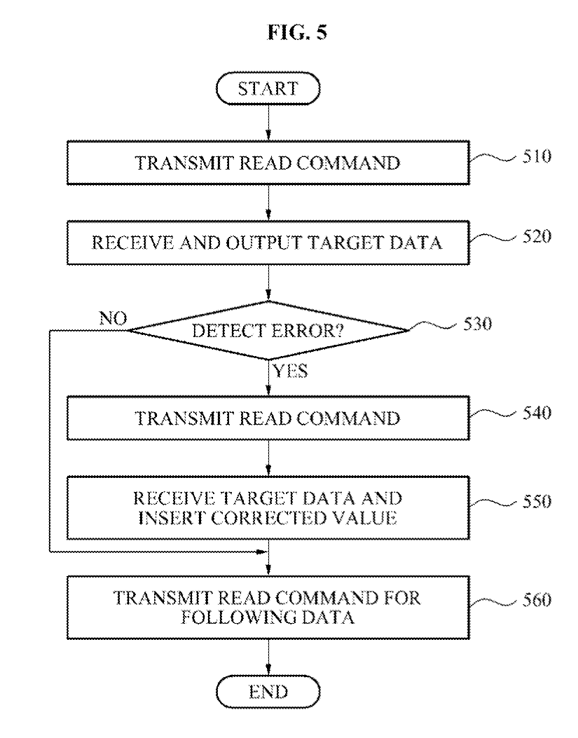

FIG. 5 is an operational flowchart illustrating an operational method of a controller according to an embodiment of the present invention.

Referring to FIG. 5, the controller may transmit a read command for reading out target data to a flash memory in operation 510.

When the target data is received from the flash memory, the controller may transmit the target data directly to a main memory without storing the target data in a buffer, in operation 520. That is, an error included in the target data may be processed afterward.

In addition, the controller may determine whether the target data being received and outputted includes an error, in operation 530. Here, the controller may detect an error using BCH codes.

When the target data does not include an error, the controller may transmit a read command with respect to following data in operation 560. Conversely, when the target data includes an error, the controller may transmit the read command again with respect to the target data in operation 540. The controller may calculate a location and a corrected value of the error present in the target data before the target data is provided again from the flash memory to the controller.

When the target data is received again by the controller, the controller may output new target data, in which the corrected value with respect to the error is inserted at a corresponding location, to the main memory in operation 550.

The methods according to the above-described example embodiments may be recorded in non-transitory computer-readable media including program instructions to implement various operations embodied by a computer. The media may also include, alone or in combination with the program instructions, data files, data structures, and the like. The program instructions recorded on the media may be those specially designed and constructed for the purposes of the example embodiments, or they may be of the kind well-known and available to those having skill in the computer software arts. Examples of non-transitory computer-readable media include magnetic media such as hard disks, floppy disks, and magnetic tape; optical media such as CD ROM discs and DVDs; magneto-optical media such as optical discs; and hardware devices that are specially configured to store and perform program instructions, such as read-only memory (ROM), random access memory (RAM), flash memory, and the like. The media may be transfer media such as optical lines, metal lines, or waveguides including a carrier wave for transmitting a signal designating the program command and the data construction. Examples of program instructions include both machine code, such as produced by a compiler, and files containing higher level code that may be executed by the computer using an interpreter. The described hardware devices may be configured to act as one or more software modules in order to perform the operations of the above-described example embodiments, or vice versa.

Although a few embodiments of the present invention have been shown and described, the present invention is not limited to the described embodiments. Instead, it would be appreciated by those skilled in the art that changes may be made to these embodiments without departing from the principles and spirit of the invention, the scope of which is defined by the claims and their equivalents.

1. An operational method of a controller for a flash memory, the operational method comprising:
receiving target data read out from the flash memory;
outputting the received target data to a main memory; and
generating an error detection syndrome related to the received target data, after or simultaneously with completion of the output of the target data.

2. The operational method of claim 1, wherein the outputting comprises outputting the received target data simultaneously with the receiving of the target data, without using a buffer provided in the controller to store the received target data.

3. The operational method of claim 1, further comprising:
reading out the target data again based on the error detection syndrome.

4. The operational method of claim 3, further comprising:
calculating, before the target data is read out again, at least one of a location of an error and a corrected value with respect to the error when the error detection syndrome indicates presence of the error in the received target data.

5. The operational method of claim 4, further comprising:
outputting new target data to the main memory by inserting the corrected value in the target data read out again.

6. The operational method of claim 1, wherein the generating comprises starting generation of the error detection syndrome using Bose, Chaudhuri, and Hocquenghem (BCH) codes during reception of the target data.

7. The operational method of claim 4, wherein the reading comprises reading again part of the target data that includes the error.

8. A non-transitory computer-readable recording medium storing a program to cause a computer to implement the method of claim 1.

9. A controller for a flash memory, the controller comprising:
an interface to receive target data read out from the flash memory and to output the received target data to a main memory; and
an error detector to generate an error detection syndrome with respect to the received target data, after or simultaneously with completion of the output of the target data.

10. The controller of claim 9, wherein the interface outputs the received target data directly to the main memory without using a buffer provided in the controller to store the received target data.

11. The controller of claim 9, further comprising a command generator to generate a command for reading out the target data again based on the error detection syndrome.

12. The controller of claim 11, wherein the error detector calculates, before the target data is read out again, at least one of a location of an error and a corrected value with respect to the error when the error detection syndrome indicates presence of the error in the received target data.

13. The controller of claim 12, wherein
the error detector generates a command for inserting the corrected value in the target data read out again so as to generate new target data, and
the interface outputs the new target data to the main memory.

14. The controller of claim 9, wherein the error detector starts generation of the error detection syndrome using Bose, Chaudhuri, and Hocquenghem (BCH) codes during reception of the target data.
